(19) United States
(12) Patent Application Publication
(10) Pub. No.: US 2023/0411390 A1
(43) Pub. Date: Dec. 21, 2023

(54) TWO-DIMENSIONAL PMOS DEVICES FOR PROVIDING CMOS IN BACK-END LAYERS OF INTEGRATED CIRCUIT DEVICES

(71) Applicant: Intel Corporation, Santa Clara, CA (US)

(72) Inventors: Kevin P. O'Brien, Portland, OR (US); Ande Kitamura, Portland, OR (US); Ashish Verma Penumatcha, Beaverton, OR (US); Carl Hugo Naylor, Portland, OR (US); Kirby Maxey, Hillsboro, OR (US); Rachel A. Steinhardt, Beaverton, OR (US); Scott B. Clendenning, Portland, OR (US); Sudarat Lee, Hillsboro, OR (US); Uygar E. Avci, Portland, OR (US); Chelsey Dorow, Portland, OR (US)

(73) Assignee: Intel Corporation, Santa Clara, CA (US)

(21) Appl. No.: 17/842,462

(22) Filed: Jun. 16, 2022

(51) Int. Cl. H01L 27/092; H03K 19/0185; H01L 29/26; H01L 23/522; H01L 23/532

(52) U.S. Cl. CPC H01L 27/092; H03K 19/018571; H01L 29/26; H01L 23/5226; H01L 23/53295; H01L 23/53228; H01L 23/53242; H01L 23/53257; H01L 23/5283

(57) ABSTRACT

In one embodiment, a transistor device includes a metal layer, a first dielectric layer comprising Hafnium and Oxygen on the metal layer, a channel layer comprising Tungsten and Selenium above the dielectric layer, a second dielectric layer comprising Hafnium and Oxygen on the channel layer, a source region comprising metal on a first end of the channel layer, a drain region comprising metal on a second end of the channel layer opposite the first end, and a metal contact on the second dielectric layer between the source regions and the drain region. In some embodiments, the transistor device may be included in a complementary metal-oxide semiconductor (CMOS) logic circuit in the back-end of an integrated circuit device, such as a processor or system-on-chip (SoC).

### BACKGROUND

Currently, it is not possible to incorporate both n-channel metal-oxide semiconductor (NMOS) and p-channel metal-oxide semiconductor (PMOS) devices in back-end layers (which may also be referred to as interconnect layers) of an integrated circuit device. Thus, it has not been possible to implement complementary metal-oxide semiconductor (CMOS) logic circuits in the back-end layers.

### BRIEF DESCRIPTION OF THE DRAWINGS

FIGS. 1A-1B illustrate example transistor devices that may be incorporated in embodiments of the present disclosure.

FIG. 2 is a cross-sectional side view of an integrated circuit device that may be included in embodiments disclosed herein.

FIG. 3 illustrates a simplified block diagram of an example integrated circuit chip architecture in accordance with embodiments of the present disclosure.

FIG. 4 illustrates a simplified block diagram of an example processor device architecture in accordance with embodiments of the present disclosure

FIG. 5 is a top view of a wafer and dies that may be included in embodiments disclosed herein.

FIG. 6 is a cross-sectional side view of an integrated circuit device assembly that may include embodiments disclosed herein.

FIG. 7 is a block diagram of an example electrical device that may include embodiments disclosed herein.

### DETAILED DESCRIPTION

In embodiments herein, novel transistor devices may be formed or included in the back-end layers of an integrated circuit device. The transistor devices may be connected such that they form complementary metal-oxide semiconductor (CMOS) logic circuits in the back-end layers of the integrated circuit device. For example, the CMOS logic circuits may include cascaded inverters that function as repeater circuits between integrated circuits, functional unit blocks (FUBs), or integrated circuit die of the integrated circuit device. As another example, the CMOS logic circuits may function as higher-voltage transistors (e.g., 1-2V) in the back-end layers as compared with the lower-voltage transistors (e.g., 0.5-1V) in the front-end layer. Further, as another example, the CMOS logic circuits may provide input/output (IO) signaling logic or circuitry between the integrated circuits, functional unit blocks (FUBs), or integrated circuit die of the integrated circuit device.

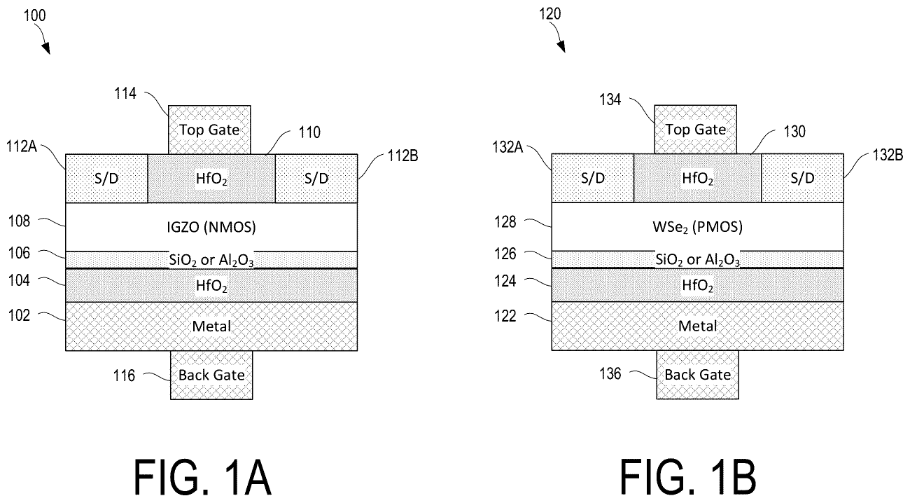

FIGS. 1A-1B illustrate example transistor devices 100, 120 that may be incorporated in embodiments of the present disclosure. The example transistor device 100 includes a metal layer 102, which may be formed from any suitable metal including Titanium nitride (TiN), Copper (Cu), Tungsten (W), Molybdenum (Mo), Ruthenium (Ru), or Cobalt (Co). As described further below, the metal layer 102 may be formed in a back-end metal layer of an integrated circuit device. The example transistor device 100 also includes a dielectric layer 104, which can be formed from Hafnium and Oxygen (e.g., HfO₂ as shown), on the metal layer 102, and a passivation layer 106 on the layer 104. The passivation layer 106 may be formed from a Silicon Oxide (e.g., SiO₂) or Aluminum Oxide (e.g., Al₂O₃) as shown, or from another material with similar properties as Silicon Oxide and Aluminum Oxide. In some embodiments, e.g., where the transistor device 100 is formed directly in the back-end layer(s) and not transferred into the back-end layer(s) after formation, the device might not include the layer 106.

The example transistor device 100 further includes an Indium Gallium Zinc Oxide (IGZO) material layer 108 on the layer 106 and another dielectric layer 110, which can be formed from Hafnium and Oxygen (e.g., HfO₂ as shown), on the IGZO layer 108. The transistor device 100 includes source/drain regions 112 co-planar with the dielectric layer 110. In some cases, the source/drain regions 112 materials may be deposited before deposition of the dielectric layer 110 (which would be deposited between the source/drain regions 112), while in other cases, the source/drain regions 112 may be deposited into etched regions within the dielectric layer 110. The source/drain regions 112 may include, in certain embodiments, a metal such as e.g., Ruthenium (Ru), Tungsten (W), or Cu, or a conductive metal oxide such as, e.g., indium tin oxide (ITO). The transistor device 100 also includes a top gate 114 formed on the layer 110 and a back gate 116 formed on the backside of the metal layer 102. The top gate 114 and back gate 116 may each include a metal, such as Cu, Co, W, Mo, TiN, or Ru, and may formed from the same type of metal as each other, in certain embodiments. In some embodiments, the top gate 114 and back gate 116 may be electrically connected such that they are provided the same voltage signals. In operation, when a voltage difference is applied to the source/drain regions 112 and to the top gate 114 and back gate 116, an n-channel may be formed in the IGZO layer 108 and the device 100 may function as an NMOS logic device.

The example transistor device 120 includes a metal layer 122, which may be formed from any suitable metal including Titanium nitride (TiN), Copper (Cu), or Cobalt (Co). Like the metal layer 102, the metal layer 122 may be formed in a back-end metal layer of an integrated circuit device. The example transistor device 120 also includes a dielectric layer 124, which can be formed from Hafnium and Oxygen (e.g., HfO₂ as shown), on the metal layer 122, and a passivation layer 126 on the layer 124. The passivation layer 126 may be formed from a Silicon Oxide (e.g., SiO₂) or Aluminum Oxide (e.g., Al₂O₃) as shown, or from another material with similar properties as Silicon Oxide and Aluminum Oxide. In some embodiments, e.g., where the transistor device 120 is formed directly in the back-end layer(s) and not transferred into the back-end layer(s) after formation, the device might not include the layer 126.

The example transistor device 120 further includes Tungsten diselenide (WSe₂) layer 128 on the layer 126 and another dielectric layer 130, which can be formed from Hafnium and Oxygen (e.g., HfO₂ as shown), on the WSe₂ layer 128. The transistor device 120 includes source/drain regions 132 on the WSe₂ layer 128 and co-planar with the dielectric layer 130. The source/drain regions 132 may, in some cases, be deposited in the same manner(s) as described above with respect to source/drain regions 112. Additionally, in other embodiments, the source/drain regions 132 may be doped regions within the WSe₂ layer 128. The source/drain regions 132 may, in certain embodiments, include a metal such as e.g., Ruthenium (Ru), Tungsten (W), or Cu, metal alloys, or may include other materials such as Antimony (Sb), Bismuth (Bi), Indium (In), or Germanium (Ge). In some embodiments, the source/drain regions 132 may be formed by stacks of such materials. As an example, the source/drain regions 132 may be a stack comprising Ru (e.g., approximately 2 nm thick) and W (e.g., 10-20 nm thick).

The transistor device 120 also includes a top gate 134 formed on the layer 130 and a back gate 136 formed on the backside of the metal layer 122. The top gate 134 and back gate 136 may each include a metal, such as Cu, W, Mo, Co, TiN, or Ru, and may be formed from the same type of metal as each other, in certain embodiments. In some embodiments, the top gate 134 and back gate 136 may be electrically connected such that they are provided the same voltage signals. In operation, when a voltage difference is applied to the source/drain regions 132 and to the top gate 134 and back gate 136, a p-channel may be formed in the WSe₂ layer 128 and the device 120 may function as a PMOS logic device.

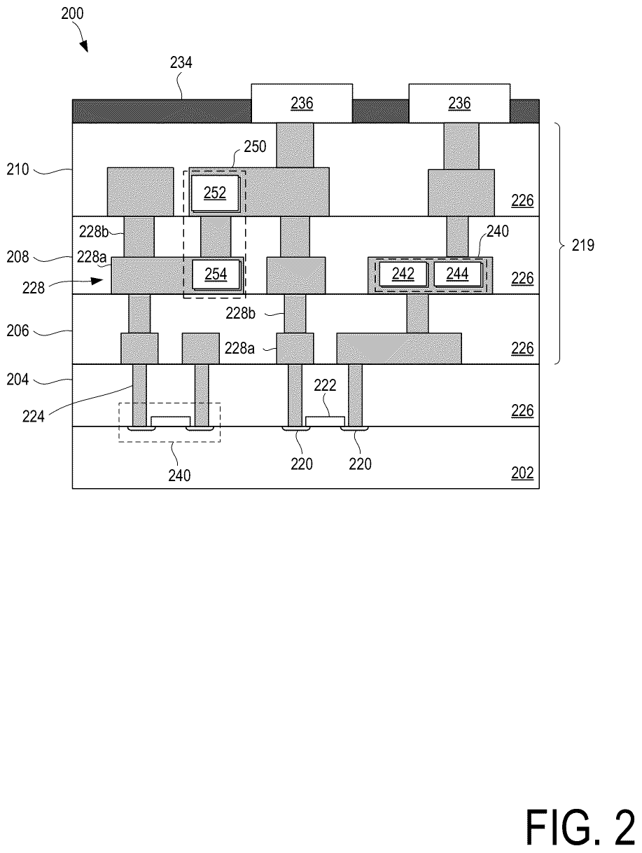

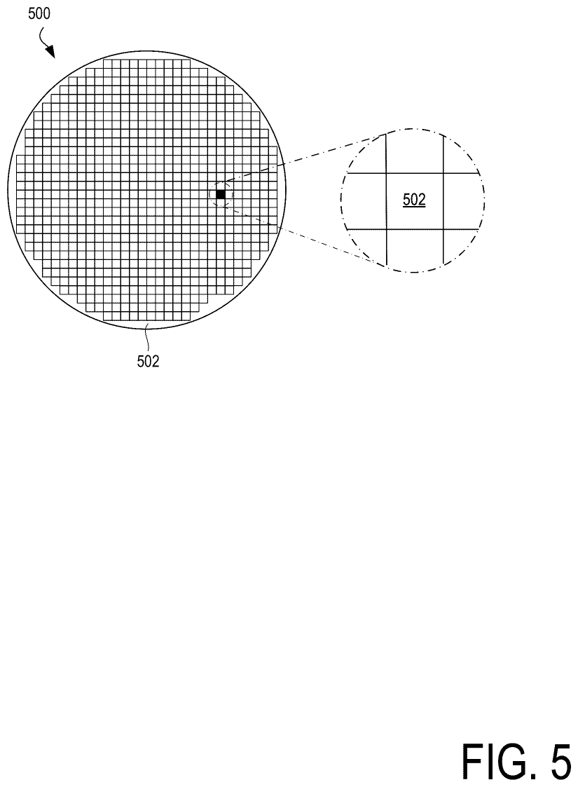

FIG. 2 is a cross-sectional side view of an integrated circuit device 200 that may be included in embodiments disclosed herein. One or more of the integrated circuit devices 200 may be included in one or more dies 502 (FIG. 5). The integrated circuit device 200 may be formed on a die substrate 202 (e.g., the wafer 500 of FIG. 5) and may be included in a die (e.g., the die 502 of FIG. 5). The die substrate 202 may be a semiconductor substrate composed of semiconductor material systems including, for example, n-type or p-type materials systems (or a combination of both). The die substrate 202 may include, for example, a crystalline substrate formed using a bulk silicon or a silicon-on-insulator (SOI) substructure. In some embodiments, the die substrate 202 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 202. Although a few examples of materials from which the die substrate 202 may be formed are described here, any material that may serve as a foundation for an integrated circuit device 200 may be used. The die substrate 202 may be part of a singulated die (e.g., the dies 502 of FIG. 5) or a wafer (e.g., the wafer 500 of FIG. 5).

The integrated circuit device 200 may include one or more device layers 204 disposed on the die substrate 202. The device layer 204 may include features of one or more transistors 240 (e.g., metal oxide semiconductor field-effect transistors (MOSFETs)) formed on the die substrate 202. The transistors 240 may include, for example, one or more source and/or drain (S/D) regions 220, a gate 222 to control current flow between the S/D regions 220, and one or more S/D contacts 224 to route electrical signals to/from the S/D regions 220. The transistors 240 may include additional features not depicted for the sake of clarity, such as device isolation regions, gate contacts, and the like. The transistors 240 are not limited to the type and configuration depicted in FIG. 2 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 2, a transistor 240 may include a gate 222 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 240 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 240 along the source-channel-drain direction, the gate electrode may consist of a U-shaped structure that includes a bottom portion substantially parallel to the surface of the die substrate 202 and two sidewall portions that are substantially perpendicular to the top surface of the die substrate 202. In other embodiments, at least one of the metal layers that form the gate electrode may simply be a planar layer that is substantially parallel to the top surface of the die substrate 202 and does not include sidewall portions substantially perpendicular to the top surface of the die substrate 202. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 220 may be formed within the die substrate 202 adjacent to the gate 222 of individual transistors 240. The S/D regions 220 may be formed using an implantation/diffusion process or an etching/deposition process, for example. In the former process, dopants such as boron, aluminum, antimony, phosphorous, or arsenic may be ion-implanted into the die substrate 202 to form the S/D regions 220. An annealing process that activates the dopants and causes them to diffuse farther into the die substrate 202 may follow the ion-implantation process. In the latter process, the die substrate 202 may first be etched to form recesses at the locations of the S/D regions 220. An epitaxial deposition process may then be carried out to fill the recesses with material that is used to fabricate the S/D regions 220. In some implementations, the S/D regions 220 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 220 may be formed using one or more alternate semiconductor materials such as germanium or a group III-V material or alloy. In further embodiments, one or more layers of metal and/or metal alloys may be used to form the S/D regions 220.

Electrical signals, such as power and/or input/output (I/O) signals, may be routed to and/or from the devices (e.g., transistors 240) of the device layer 204 through one or more interconnect layers disposed on the device layer 204 (illustrated in FIG. 2 as interconnect layers 206-210). For example, electrically conductive features of the device layer 204 (e.g., the gate 222 and the S/D contacts 224) may be electrically coupled with the interconnect structures 228 of the interconnect layers 206-210. The one or more interconnect layers 206-210 may form a metallization stack (also referred to as an “ILD stack”) 219 of the integrated circuit device 200.

The interconnect structures 228 may be arranged within the interconnect layers 206-210 to route electrical signals according to a wide variety of designs; in particular, the arrangement is not limited to the particular configuration of interconnect structures 228 depicted in FIG. 2. Although a particular number of interconnect layers 206-210 is depicted in FIG. 2, embodiments of the present disclosure include integrated circuit devices having more or fewer interconnect layers than depicted. For example, certain embodiments may include between 10-20 interconnect layers.

In some embodiments, the interconnect structures 228 may include lines 228a and/or vias 228b filled with an electrically conductive material such as a metal. The lines 228a may be arranged to route electrical signals in a direction of a plane that is substantially parallel with a surface of the die substrate 202 upon which the device layer 204 is formed. For example, the lines 228a may route electrical signals in a direction in and out of the page and/or in a direction across the page from the perspective of FIG. 2. The vias 228b may be arranged to route electrical signals in a direction of a plane that is substantially perpendicular to the surface of the die substrate 202 upon which the device layer 204 is formed. In some embodiments, the vias 228b may electrically couple lines 228a of different interconnect layers 206-210 together.

The interconnect layers 206-210 may include a dielectric material 226 disposed between the interconnect structures 228, as shown in FIG. 2. In some embodiments, dielectric material 226 disposed between the interconnect structures 228 in different ones of the interconnect layers 206-210 may have different compositions; in other embodiments, the composition of the dielectric material 226 between different interconnect layers 206-210 may be the same. The device layer 204 may include a dielectric material 226 disposed between the transistors 240 and a bottom layer of the metallization stack as well. The dielectric material 226 included in the device layer 204 may have a different composition than the dielectric material 226 included in the interconnect layers 206-210; in other embodiments, the composition of the dielectric material 226 in the device layer 204 may be the same as a dielectric material 226 included in any one of the interconnect layers 206-210.

A first interconnect layer 206 (referred to as Metal 1 or “M1”) may be formed directly on the device layer 204. In some embodiments, the first interconnect layer 206 may include lines 228a and/or vias 228b, as shown. The lines 228a of the first interconnect layer 206 may be coupled with contacts (e.g., the S/D contacts 224) of the device layer 204. The vias 228b of the first interconnect layer 206 may be coupled with the lines 228a of a second interconnect layer 208.

The second interconnect layer 208 (referred to as Metal 2 or “M2”) may be formed directly on the first interconnect layer 206. In some embodiments, the second interconnect layer 208 may include via 228b to couple the lines 228 of the second interconnect layer 208 with the lines 228a of a third interconnect layer 210. Although the lines 228a and the vias 228b are structurally delineated with a line within individual interconnect layers for the sake of clarity, the lines 228a and the vias 228b may be structurally and/or materially contiguous (e.g., simultaneously filled during a dual-damascene process) in some embodiments.

The third interconnect layer 210 (referred to as Metal 3 or “M3”) (and additional interconnect layers, as desired) may be formed in succession on the second interconnect layer 208 according to similar techniques and configurations described in connection with the second interconnect layer 208 or the first interconnect layer 206. In some embodiments, the interconnect layers that are “higher up” in the metallization stack 219 in the integrated circuit device 200 (i.e., farther away from the device layer 204) may be thicker that the interconnect layers that are lower in the metallization stack 219, with lines 228a and vias 228b in the higher interconnect layers being thicker than those in the lower interconnect layers.

In embodiments of the present disclosure, the interconnect layers 206-210 may also include CMOS logic circuits (e.g., 240, 250) that include NMOS devices (e.g., 242, 252) and PMOS devices (e.g., 244, 254). The NMOS devices 242, 252 and PMOS devices 244, 254 may be implemented in the same or similar manner as the NMOS device 100 and PMOS 120 device of FIGS. 1A-1B, respectively. In some embodiments, a CMOS logic circuit may be implemented with NMOS and PMOS devices on the same interconnect layer, e.g., as shown with the CMOS logic circuit 240. However, in other embodiments, a CMOS logic circuit may be implemented with NMOS and PMOS devices on different interconnect layers, e.g., as shown with the CMOS logic circuit 250. Some embodiments may include a combination of such logic circuits, as shown in FIG. 2. In certain embodiments with CMOS logic circuits having NMOS and PMOS devices on different layers, the NMOS devices may be located on the higher layer(s) as shown.

Ins some embodiments, the NMOS and PMOS devices may be formed in the back-end layers as part of the manufacturing process of the integrated circuit device 200. For example, the logic circuit 240 may be formed during the fabrication process of the second interconnect/M2 layer. In other embodiments, the NMOS and PMOS devices may be fabricated as a separate process and then placed into the interconnect layers during the manufacturing process of the integrated circuit device 200.

The integrated circuit device 200 may include a solder resist material 234 (e.g., polyimide or similar material) and one or more conductive contacts 236 formed on the interconnect layers 206-210. In FIG. 2, the conductive contacts 236 are illustrated as taking the form of bond pads. The conductive contacts 236 may be electrically coupled with the interconnect structures 228 and configured to route the electrical signals of the transistor(s) 240 to external devices. For example, solder bonds may be formed on the one or more conductive contacts 236 to mechanically and/or electrically couple an integrated circuit die including the integrated circuit device 200 with another component (e.g., a printed circuit board). The integrated circuit device 200 may include additional or alternate structures to route the electrical signals from the interconnect layers 206-210; for example, the conductive contacts 236 may include other analogous features (e.g., posts) that route the electrical signals to external components.

In some embodiments in which the integrated circuit device 200 is a double-sided die, the integrated circuit device 200 may include another metallization stack (not shown) on the opposite side of the device layer(s) 204. This metallization stack may include multiple interconnect layers as discussed above with reference to the interconnect layers 206-210, to provide conductive pathways (e.g., including conductive lines and vias) between the device layer(s) 204 and additional conductive contacts (not shown) on the opposite side of the integrated circuit device 200 from the conductive contacts 236.

In other embodiments in which the integrated circuit device 200 is a double-sided die, the integrated circuit device 200 may include one or more through silicon vias (TSVs) through the die substrate 202; these TSVs may make contact with the device layer(s) 204, and may provide conductive pathways between the device layer(s) 204 and additional conductive contacts (not shown) on the opposite side of the integrated circuit device 200 from the conductive contacts 236. In some embodiments, TSVs extending through the substrate can be used for routing power and ground signals from conductive contacts on the opposite side of the integrated circuit device 200 from the conductive contacts 236 to the transistors 240 and any other components integrated into the die 200, and the metallization stack 219 can be used to route I/O signals from the conductive contacts 236 to transistors 240 and any other components integrated into the die 200.

Multiple integrated circuit devices 200 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

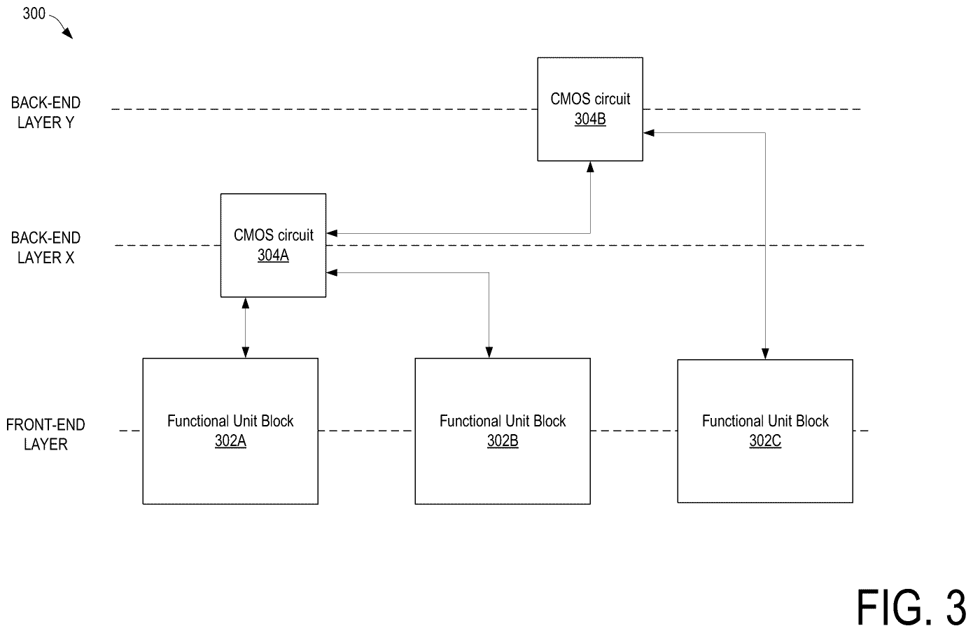

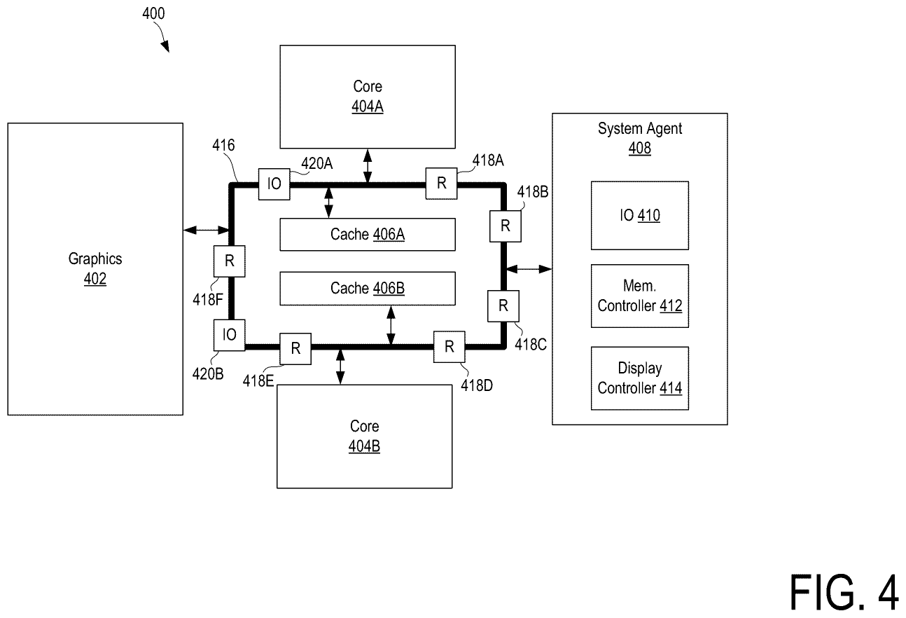

FIG. 3 illustrates a simplified block diagram of an example integrated circuit chip architecture 300 in accordance with embodiments of the present disclosure. The integrated circuit chip architecture 300 may be implemented in any suitable integrated circuit chip device, such as a processor (e.g., as shown in FIG. 4) or a system-on-chip that includes one or more processors, memory, and/or other components on a chip.

The example integrated circuit chip architecture 300 includes a set of functional unit blocks (FUBs) 302 in a front-end layer of an integrated circuit device. The FUBs 302 may include respective sets of transistors that implement particular functions in the integrated circuit devices. For example, a FUB may implement an adder, a decoder, a cache, etc. Multiple FUBs 302 may be connected in such a way to implement larger logic circuits within the integrated circuit device. In the example shown, the FUBs 302 are connected between CMOS logic circuits 304, which reside in different back-end layers of the integrated circuit device. For instance, the FUB 302A is connected to the FUB 302B through the CMOS logic circuit 304A, while the FUB 302A is connected to the FUB 302C through the CMOS logic circuits 304A and 304B. The CMOS logic circuits 304 may be implemented with transistor devices such as the devices 100, 120 of FIGS. 1A-1B.

FIG. 4 illustrates a simplified block diagram of an example processor device architecture 400 in accordance with embodiments of the present disclosure. The example architecture 400 includes graphics processing circuitry 402, two processing cores 404, cache units 406, and a system agent 408, which includes input-output (IO) circuitry 410, memory controller circuitry 412, and display controller circuitry 414, connected to one another via a ring interconnect 416. The architecture 400 may include additional, fewer, or other components than those shown. In certain embodiments, graphics processing circuitry 402, two processing cores 404, cache units 406, and a system agent 408, which includes input-output (IO) circuitry 410, memory controller circuitry 412, and display controller circuitry 414 may be implemented using transistor devices in the front-end layer of device (e.g., the layer 204 in FIG. 2), while the interconnect 416 is implemented in the interconnect layers of the device (e.g., the interconnect layers 206-210 in FIG. 2).

In the example shown, the interconnect 416 includes a number of repeaters 418 between components of the architecture 400. The repeaters 418 may be implemented as CMOS logic circuits as described above. For example, the repeaters 418 may be formed as cascaded inverters formed using the transistors devices shown in FIGS. 1A-1B. Any suitable number of repeaters 418 may be used between components of the architecture 400, with the number determined based on the interconnect length between the components of the architecture 400. Further, in the example shown, the interconnect 416 also includes IO logic circuits 420, e.g., between the graphics processing circuitry 402 and the respective cores 404. The IO logic circuits 420 may include transistors devices, such as the transistors devices shown in FIGS. 1A-1B.

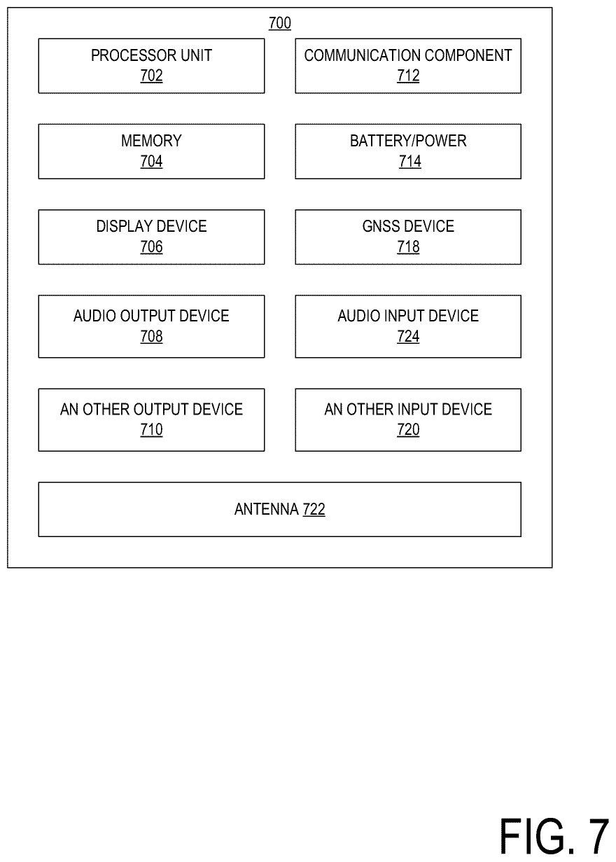

FIG. 5 is a top view of a wafer 500 and dies 502 that may incorporate any of the embodiments disclosed herein. The wafer 500 may be composed of semiconductor material and may include one or more dies 502 having integrated circuit structures formed on a surface of the wafer 500. The individual dies 502 may be a repeating unit of an integrated circuit product that includes any suitable integrated circuit. After the fabrication of the semiconductor product is complete, the wafer 500 may undergo a singulation process in which the dies 502 are separated from one another to provide discrete “chips” of the integrated circuit product. The die 502 may include one or more transistors (e.g., some of the transistors 240 of FIG. 2, discussed below), supporting circuitry to route electrical signals to the transistors, passive components (e.g., signal traces, resistors, capacitors, or inductors), and/or any other integrated circuit components. In some embodiments, the wafer 500 or the die 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processor unit (e.g., the processor unit 702 of FIG. 7) or other logic that is configured to store information in the memory devices or execute instructions stored in the memory array.

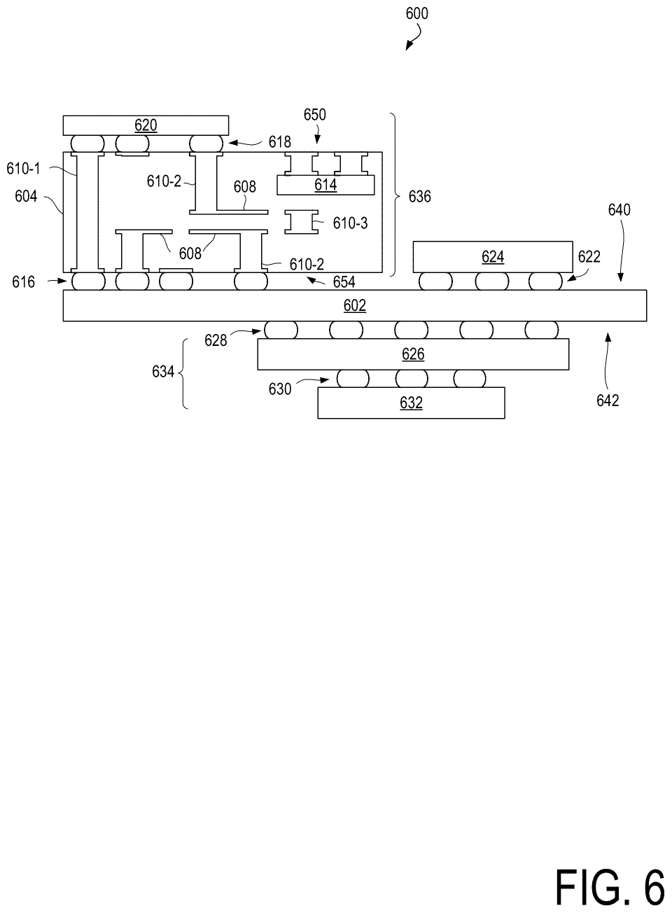

FIG. 6 is a cross-sectional side view of an integrated circuit device assembly 600 that may include any of the embodiments disclosed herein. The integrated circuit device assembly 600 includes a number of components disposed on a circuit board 602 (which may be a motherboard, system board, mainboard, etc.). The integrated circuit device assembly 600 includes components disposed on a first face 640 of the circuit board 602 and an opposing second face 642 of the circuit board 602; generally, components may be disposed on one or both faces 640 and 642.

In some embodiments, the circuit board 602 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 602. In other embodiments, the circuit board 602 may be a non-PCB substrate. The integrated circuit device assembly 600 illustrated in FIG. 6 includes a package-on-interposer structure 636 coupled to the first face 640 of the circuit board 602 by coupling components 616. The coupling components 616 may electrically and mechanically couple the package-on-interposer structure 636 to the circuit board 602, and may include solder balls (as shown in FIG. 6), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 636 may include an integrated circuit component 620 coupled to an interposer 604 by coupling components 618. The coupling components 618 may take any suitable form for the application, such as the forms discussed above with reference to the coupling components 616. Although a single integrated circuit component 620 is shown in FIG. 6, multiple integrated circuit components may be coupled to the interposer 604; indeed, additional interposers may be coupled to the interposer 604. The interposer 604 may provide an intervening substrate used to bridge the circuit board 602 and the integrated circuit component 620.

The integrated circuit component 620 may be a packaged or unpacked integrated circuit product that includes one or more integrated circuit dies (e.g., the die 502 of FIG. 5, the integrated circuit device 200 of FIG. 2) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 620, a single monolithic integrated circuit die comprises solder bumps attached to contacts on the die. The solder bumps allow the die to be directly attached to the interposer 604. The integrated circuit component 620 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 620 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 620 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 620 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 604 may spread connections to a wider pitch or reroute a connection to a different connection. For example, the interposer 604 may couple the integrated circuit component 620 to a set of ball grid array (BGA) conductive contacts of the coupling components 616 for coupling to the circuit board 602. In the embodiment illustrated in FIG. 6, the integrated circuit component 620 and the circuit board 602 are attached to opposing sides of the interposer 604; in other embodiments, the integrated circuit component 620 and the circuit board 602 may be attached to a same side of the interposer 604. In some embodiments, three or more components may be interconnected by way of the interposer 604.

In some embodiments, the interposer 604 may be formed as a PCB, including multiple metal layers separated from one another by layers of dielectric material and interconnected by electrically conductive vias. In some embodiments, the interposer 604 may be formed of an epoxy resin, a fiberglass-reinforced epoxy resin, an epoxy resin with inorganic fillers, a ceramic material, or a polymer material such as polyimide. In some embodiments, the interposer 604 may be formed of alternate rigid or flexible materials that may include the same materials described above for use in a semiconductor substrate, such as silicon, germanium, and other group III-V and group IV materials. The interposer 604 may include metal interconnects 608 and vias 610, including but not limited to through hole vias 610-1 (that extend from a first face 650 of the interposer 604 to a second face 654 of the interposer 604), blind vias 610-2 (that extend from the first or second faces 650 or 654 of the interposer 604 to an internal metal layer), and buried vias 610-3 (that connect internal metal layers).

In some embodiments, the interposer 604 can comprise a silicon interposer. Through silicon vias (TSV) extending through the silicon interposer can connect connections on a first face of a silicon interposer to an opposing second face of the silicon interposer. In some embodiments, an interposer 604 comprising a silicon interposer can further comprise one or more routing layers to route connections on a first face of the interposer 604 to an opposing second face of the interposer 604.

The interposer 604 may further include embedded devices 614, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 604. The package-on-interposer structure 636 may take the form of any of the package-on-interposer structures known in the art. In embodiments where the interposer is a non-printed circuit board

The integrated circuit device assembly 600 may include an integrated circuit component 624 coupled to the first face 640 of the circuit board 602 by coupling components 622. The coupling components 622 may take the form of any of the embodiments discussed above with reference to the coupling components 616, and the integrated circuit component 624 may take the form of any of the embodiments discussed above with reference to the integrated circuit component 620.

The integrated circuit device assembly 600 illustrated in FIG. 6 includes a package-on-package structure 634 coupled to the second face 642 of the circuit board 602 by coupling components 628. The package-on-package structure 634 may include an integrated circuit component 626 and an integrated circuit component 632 coupled together by coupling components 630 such that the integrated circuit component 626 is disposed between the circuit board 602 and the integrated circuit component 632. The coupling components 628 and 630 may take the form of any of the embodiments of the coupling components 616 discussed above, and the integrated circuit components 626 and 632 may take the form of any of the embodiments of the integrated circuit component 620 discussed above. The package-on-package structure 634 may be configured in accordance with any of the package-on-package structures known in the art.

FIG. 7 is a block diagram of an example electrical device 700 that may include one or more of the embodiments disclosed herein. For example, any suitable ones of the components of the electrical device 700 may include one or more of the integrated circuit device assemblies 600, integrated circuit components 620, integrated circuit devices 200, or integrated circuit dies 502 disclosed herein. A number of components are illustrated in FIG. 7 as included in the electrical device 700, but any one or more of these components may be omitted or duplicated, as suitable for the application. In some embodiments, some or all of the components included in the electrical device 700 may be attached to one or more motherboards mainboards, or system boards. In some embodiments, one or more of these components are fabricated onto a single system-on-a-chip (SoC) die.

Additionally, in various embodiments, the electrical device 700 may not include one or more of the components illustrated in FIG. 7, but the electrical device 700 may include interface circuitry for coupling to the one or more components. For example, the electrical device 700 may not include a display device 706, but may include display device interface circuitry (e.g., a connector and driver circuitry) to which a display device 706 may be coupled. In another set of examples, the electrical device 700 may not include an audio input device 724 or an audio output device 708, but may include audio input or output device interface circuitry (e.g., connectors and supporting circuitry) to which an audio input device 724 or audio output device 708 may be coupled.

The electrical device 700 may include one or more processor units 702 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 702 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 700 may include a memory 704, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 704 may include memory that is located on the same integrated circuit die as the processor unit 702. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 700 can comprise one or more processor units 702 that are heterogeneous or asymmetric to another processor unit 702 in the electrical device 700. There can be a variety of differences between the processing units 702 in a system in terms of a spectrum of metrics of merit including architectural, microarchitectural, thermal, power consumption characteristics, and the like. These differences can effectively manifest themselves as asymmetry and heterogeneity among the processor units 702 in the electrical device 700.

In some embodiments, the electrical device 700 may include a communication component 712 (e.g., one or more communication components). For example, the communication component 712 can manage wireless communications for the transfer of data to and from the electrical device 700. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 712 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 712 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 712 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 712 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 712 may operate in accordance with other wireless protocols in other embodiments. The electrical device 700 may include an antenna 722 to facilitate wireless communications and/or to receive other wireless communications (such as AM or FM radio transmissions).

In some embodiments, the communication component 712 may manage wired communications, such as electrical, optical, or any other suitable communication protocols (e.g., IEEE 802.3 Ethernet standards). As noted above, the communication component 712 may include multiple communication components. For instance, a first communication component 712 may be dedicated to shorter-range wireless communications such as Wi-Fi or Bluetooth, and a second communication component 712 may be dedicated to longer-range wireless communications such as global positioning system (GPS), EDGE, GPRS, CDMA, WiMAX, LTE, EV-DO, or others. In some embodiments, a first communication component 712 may be dedicated to wireless communications, and a second communication component 712 may be dedicated to wired communications.

The electrical device 700 may include battery/power circuitry 714. The battery/power circuitry 714 may include one or more energy storage devices (e.g., batteries or capacitors) and/or circuitry for coupling components of the electrical device 700 to an energy source separate from the electrical device 700 (e.g., AC line power).

The electrical device 700 may include a display device 706 (or corresponding interface circuitry, as discussed above). The display device 706 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 700 may include an audio output device 708 (or corresponding interface circuitry, as discussed above). The audio output device 708 may include any embedded or wired or wirelessly connected external device that generates an audible indicator, such speakers, headsets, or earbuds.

The electrical device 700 may include an audio input device 724 (or corresponding interface circuitry, as discussed above). The audio input device 724 may include any embedded or wired or wirelessly connected device that generates a signal representative of a sound, such as microphones, microphone arrays, or digital instruments (e.g., instruments having a musical instrument digital interface (MIDI) output). The electrical device 700 may include a Global Navigation Satellite System (GNSS) device 718 (or corresponding interface circuitry, as discussed above), such as a Global Positioning System (GPS) device. The GNSS device 718 may be in communication with a satellite-based system and may determine a geolocation of the electrical device 700 based on information received from one or more GNSS satellites, as known in the art.

The electrical device 700 may include another output device 710 (or corresponding interface circuitry, as discussed above). Examples of the other output device 710 may include an audio codec, a video codec, a printer, a wired or wireless transmitter for providing information to other devices, or an additional storage device.

The electrical device 700 may include another input device 720 (or corresponding interface circuitry, as discussed above). Examples of the other input device 720 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 700 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 700 may be any other electronic device that processes data. In some embodiments, the electrical device 700 may comprise multiple discrete physical components. Given the range of devices that the electrical device 700 can be manifested as in various embodiments, in some embodiments, the electrical device 700 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is a transistor device comprising: a metal layer; a first dielectric layer on the metal layer, the first dielectric layer comprising Hafnium and Oxygen; a channel layer above the dielectric layer comprising Tungsten and Selenium; a second dielectric layer on the channel layer, the second dielectric layer comprising Hafnium and Oxygen; a source region comprising metal at a first end of the channel layer; a drain region comprising metal at a second end of the channel layer opposite the first end; and a metal contact on the second dielectric layer and between the source regions and the drain region.

Example 2 includes the subject matter of Example 1, further comprising a passivation layer between the channel layer and the first dielectric layer, the passivation layer comprising one or more of Silicon, Aluminum, and Oxygen.

Example 3 includes the subject matter of Example 1 or 2, wherein the source region and the drain region are on the channel region and co-planar with the second dielectric layer.

Example 4 includes the subject matter of Example 1 or 2, wherein the source region and the drain region are doped regions within the channel region.

Example 5 includes the subject matter of any one of Examples 1-4, wherein the metal layer comprises one or more of Titanium, Nitrogen, Copper, Tungsten, Molybdenum, Ruthenium and Cobalt.

Example 6 includes the subject matter of any one of Examples 1-5, wherein the source region and the drain region comprise one or more of Ruthenium, Copper, Tungsten, Indium, and Tin.

Example 7 includes the subject matter of any one of Examples 1-6, wherein the metal contact comprises one or more of Ruthenium, Tungsten, Copper, Tin, Antimony, Bismuth, Indium, and Germanium.

Example 8 includes the subject matter of any one of Examples 1-7, wherein the metal contact is a first metal contact, and the device further comprises a second metal contact on a side of the metal layer opposite the first dielectric layer.

Example 9 includes the subject matter of Example 8, wherein the second metal contact comprises one or more of Ruthenium, Copper, Tungsten, Titanium and Nitrogen.

Example 10 includes the subject matter of Example 8, wherein the first metal contact and second metal contact are electrically connected.

Example 11 is an integrated circuit apparatus comprising: a first integrated circuit component in a front-end layer of the integrated circuit apparatus; a second integrated circuit component in the front-end layer; and an electrical interconnect coupling the first integrated circuit component and the second integrated circuit component, wherein the interconnect is in one or more back-end layers of the integrated circuit apparatus and comprises a plurality of transistor devices in a complementary metal-oxide semiconductor (CMOS) logic circuit.

Example 12 includes the subject matter of Example 11, wherein the CMOS logic circuit is a first CMOS logic circuit, and the interconnect further comprises a second CMOS logic circuit.

Example 13 includes the subject matter of Example 12, wherein the first CMOS logic circuit and second CMOS logic circuit are in different back-end layers of the integrated circuit apparatus.

Example 14 includes the subject matter of any one of Examples 11-13, wherein the first CMOS logic circuit or second CMOS logic circuit comprises an inverter.

Example 15 includes the subject matter of any one of Examples 11-14, wherein the first CMOS logic circuit or second CMOS logic circuit comprises a transistor device of any one of Examples 1-8.

Example 16 includes the subject matter of any one of Examples 11-15, wherein the first integrated circuit component is a first functional unit block circuit and the second integrated circuit component is a second functional unit block circuit.

Example 17 includes the subject matter of any one of Examples 11-16, wherein the integrated circuit apparatus is a processor or system-on-chip (SoC).

Example 18 is a processor comprising: one or more processor cores in a front-end layer of a chip of the processor; one or more cache units in the front-end layer; and an interconnect coupling the processor cores and the cache units, the interconnect in one or more back-end layers of the chip of the processor and comprising a plurality of transistor devices in a complementary metal-oxide semiconductor (CMOS) logic circuit.

Example 19 includes the subject matter of Example 18, wherein the CMOS logic circuit is a first CMOS logic circuit, and the interconnect further comprises a second CMOS logic circuit.

Example 20 includes the subject matter of Example 18 or 19, wherein the first CMOS logic circuit and second CMOS logic circuit are in different back-end layers of the integrated circuit apparatus.

Example 21 includes the subject matter of any one of Examples 18-20, wherein the first CMOS logic circuit or second CMOS logic circuit comprises an inverter.

Example 22 includes the subject matter of any one of Examples 18-21, wherein the CMOS logic circuit comprises a transistor device of any one of Examples 1-8.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. A transistor device comprising:
a metal layer;
a first dielectric layer on the metal layer, the first dielectric layer comprising Hafnium and Oxygen;
a channel layer above the dielectric layer comprising Tungsten and Selenium;
a second dielectric layer on the channel layer, the second dielectric layer comprising Hafnium and Oxygen;
a source region comprising metal at a first end of the channel layer;
a drain region comprising metal at a second end of the channel layer opposite the first end; and
a metal contact on the second dielectric layer and between the source regions and the drain region.

2. The transistor device of claim 1, further comprising a passivation layer between the channel layer and the first dielectric layer, the passivation layer comprising one or more of Silicon, Aluminum, and Oxygen.

3. The transistor device of claim 1, wherein the source region and the drain region are on the channel region and co-planar with the second dielectric layer.

4. The transistor device of claim 1, wherein the source region and the drain region are doped regions within the channel region.

5. The transistor device of claim 1, wherein the metal layer comprises one or more of Titanium, Nitrogen, Copper, Tungsten, Molybdenum, Ruthenium and Cobalt.

6. The transistor device of claim 1, wherein the source region and the drain region comprise one or more of Ruthenium, Tungsten, Copper, Tin, Antimony, Bismuth, Indium, and Germanium.

7. The transistor device of claim 1, wherein the metal contact comprises one or more of Titanium, Nitrogen, Copper, Tungsten, Molybdenum, Ruthenium and Cobalt.

8. The transistor device of claim 1, wherein the metal contact is a first metal contact, and the device further comprises a second metal contact on a side of the metal layer opposite the first dielectric layer.

9. The transistor device of claim 8, wherein the second metal contact comprises one or more of Ruthenium, Copper, Tungsten, Titanium and Nitrogen.

10. The transistor device of claim 8, wherein the first metal contact and second metal contact are electrically connected.

11. An integrated circuit apparatus comprising:
a first integrated circuit component in a front-end layer of the integrated circuit apparatus;
a second integrated circuit component in the front-end layer; and
an electrical interconnect coupling the first integrated circuit component and the second integrated circuit component, wherein the interconnect is in one or more back-end layers of the integrated circuit apparatus and comprises a plurality of transistor devices in a complementary metal-oxide semiconductor (CMOS) logic circuit.

12. The apparatus of claim 11, wherein the CMOS logic circuit is a first CMOS logic circuit, and the interconnect further comprises a second CMOS logic circuit.

13. The apparatus of claim 12, wherein the first CMOS logic circuit and second CMOS logic circuit are in different back-end layers of the integrated circuit apparatus.

14. The apparatus of claim 11, wherein the CMOS logic circuit comprises an inverter.

15. The apparatus of claim 11, wherein the CMOS logic circuit comprises a transistor device comprising:
a metal layer;
a first dielectric layer on the metal layer, the first dielectric layer comprising Hafnium and Oxygen;
a channel layer above the dielectric layer comprising Tungsten and Selenium;
a second dielectric layer on the channel layer, the second dielectric layer comprising Hafnium and Oxygen;
a source region comprising metal on a first end of the channel layer;
a drain region comprising metal on a second end of the channel layer opposite the first end; and
a metal contact on the second dielectric layer and between the source regions and the drain region.

16. The apparatus of claim 11, wherein the first integrated circuit component is a first functional unit block circuit and the second integrated circuit component is a second functional unit block circuit.

17. The apparatus of claim 11, wherein the integrated circuit apparatus is a processor or system-on-chip (SoC).

18. A processor comprising:
one or more processor cores in a front-end layer of a chip of the processor;
one or more cache units in the front-end layer; and
an interconnect coupling the processor cores and the cache units, the interconnect in one or more back-end layers of the chip of the processor and comprising a plurality of transistor devices in a complementary metal-oxide semiconductor (CMOS) logic circuit.

19. The processor of claim 18, wherein the CMOS logic circuit is a first CMOS logic circuit, and the interconnect further comprises a second CMOS logic circuit.

20. The processor of claim 19, wherein the first CMOS logic circuit and second CMOS logic circuit are in different back-end layers of the integrated circuit apparatus.

21. The processor of claim 18, wherein the first CMOS logic circuit or second CMOS logic circuit comprises an inverter.

22. The processor of claim 18, wherein the CMOS logic circuit comprises a transistor device comprising:
a metal layer;
a first dielectric layer on the metal layer, the first dielectric layer comprising Hafnium and Oxygen;
a channel layer above the dielectric layer comprising Tungsten and Selenium;
a second dielectric layer on the channel layer, the second dielectric layer comprising Hafnium and Oxygen;
a source region comprising metal on a first end of the channel layer;
a drain region comprising metal on a second end of the channel layer opposite the first end; and
a metal contact on the second dielectric layer and between the source regions and the drain region.
